(19) United States
(12) Patent Application Publication
(10) Pub. No.: US 2025/0391635 A1
(43) Pub. Date: Dec. 25, 2025

(54) ELECTRON BEAM ADJUSTMENT METHOD, ELECTRON BEAM APPARATUS, AND STORAGE MEDIUM

(71) Applicant: NuFlare Technology, Inc., Yokohama-shi (JP)

(72) Inventor: Nobuo MIYAMOTO, Yokohama-shi (JP)

(73) Assignee: NuFlare Technology, Inc., Yokohama-shi (JP)

(21) Appl. No.: 19/211,397

(22) Filed: May 19, 2025

(30) Foreign Application Priority Data
Jun. 20, 2024 (JP) 2024-099750

(51) Int. Cl. H01J 37/304; H01J 37/075; H01J 37/317

(52) U.S. Cl. CPC H01J 37/304; H01J 37/075; H01J 37/3174; H01J 2237/06308; H01J 2237/24564

(57) ABSTRACT

According to one aspect of the present invention, an electron beam adjustment method, includes: setting, to a predetermined value, a temperature of a cathode in a thermal electron source; changing a bias voltage applied to a Wehnelt electrode while maintaining the temperature of the cathode at the predetermined value; measuring an emission current in a case that the bias voltage is changed while maintaining the temperature of the cathode at the predetermined value; and calculating a determination parameter based on an amount of change in the emission current in a case that the bias voltage is changed, wherein each of the changing of the bias voltage, the measuring of the emission current, and the calculating of the determination parameter is repeated within a range where the determination parameter does not exceed a threshold value while maintaining the temperature of the cathode at the predetermined value.

### CROSS-REFERENCE TO RELATED APPLICATION

This application is based upon and claims the benefit of priority from prior Japanese Patent Application No. 2024-099750 filed on Jun. 20, 2024 in Japan, the entire contents of which are incorporated herein by reference.

### BACKGROUND OF THE INVENTION

### Field of the Invention

One aspect of the present invention relates to an electron beam adjustment method, an electron beam apparatus, and a non-transitory computer-readable storage medium storing a program, and relates to a method for adjusting the operating conditions of a cathode of a thermal electron source that emits an electron beam.

### Related Art

Lithography technology, which is responsible for the advancement of miniaturization of semiconductor devices, is an extremely important process that is the only pattern generation process among the semiconductor manufacturing processes. In recent years, as LSIs have become more highly integrated, the circuit line width required for semiconductor devices has become smaller year by year. Here, electron beam writing (or “drawing”) technology is basically excellent in terms of resolution, and a mask pattern is written on a mask blank using an electron beam.

For example, there is a writing apparatus using multiple beams. Compared to the case of writing using a single electron beam, using multiple beams allows irradiation using a large amount of beams at a time, resulting in a significant improvement in throughput. In such a writing apparatus based on the multi-beam method, for example, electron beams emitted from a thermal electron source pass through a mask having a plurality of holes to form multiple beams, and each of the multiple beams is subjected to blanking control so that each beam that is not blocked is demagnified by an optical system to reduce a mask image, deflected by a deflector, and emitted to a desired position on a target object.

In a thermal electron source that emits an electron beam, in order to obtain the desired emission current at the lowest possible cathode temperature, the operating point of the thermal electron source is often set near the boundary between the space charge limited region and the temperature limited region, but not within the temperature limited region. Conventionally, there has been proposed a method in which the relationship between the emission current and the bias voltage is measured for each cathode temperature until the bias saturation point is reached and the operating point is determined from the characteristics or a method in which the bias voltage for maintaining the emission current constant is measured each time while changing the cathode temperature and a position where the amount of change in bias voltage is sufficiently small relative to the amount of change in temperature is searched for as an operating point (see Published Unexamined Japanese Patent Application No. 2011-228501, for example).

However, when adjusting an electron beam using a conventional method, it is necessary to measure data over a wide range up to the deep part of the temperature limited region in the process of obtaining such an operating point. When an electron beam is emitted in the temperature limited region, there is a problem in that there are portions with locally high intensity in the current density distribution of the beam and accordingly, the aperture substrate and the like that are struck by the electron beam may be damaged. For this reason, it is required to search for the operating point in a path that does not go deep into the temperature limited region.

### BRIEF SUMMARY OF THE INVENTION

According to one aspect of the present invention, an electron beam adjustment method, includes: setting, to a predetermined value, a temperature of a cathode in a thermal electron source configured to have the cathode, an anode electrode controlled to have a positive potential with respect to the cathode, and a Wehnelt electrode arranged between the cathode and the anode electrode and controlled to have a negative potential with respect to the cathode, and emit an electron beam from the cathode to the anode electrode;
changing a bias voltage applied to the Wehnelt electrode while maintaining the temperature of the cathode at the predetermined value;
measuring an emission current in a case that the bias voltage is changed while maintaining the temperature of the cathode at the predetermined value; and
calculating a determination parameter based on an amount of change in the emission current in a case that the bias voltage is changed,
wherein each of the changing of the bias voltage, the measuring of the emission current, and the calculating of the determination parameter is repeated within a range where the determination parameter does not exceed a threshold value while maintaining the temperature of the cathode at the predetermined value.

According to another aspect of the present invention, an electron beam apparatus, includes:
a thermal electron source configured to have a cathode, an anode electrode controlled to have a positive potential with respect to the cathode, and a Wehnelt electrode arranged between the cathode and the anode electrode and controlled to have a negative potential with respect to the cathode, and emit an electron beam from the cathode to the anode electrode;
a temperature setting circuit configured to set a temperature of the cathode to a predetermined value;
a bias voltage control circuit configured to change a bias voltage applied to the Wehnelt electrode while maintaining the temperature of the cathode at the predetermined value;
an emission current measurement circuit configured to measure an emission current in a case that the bias voltage is changed while maintaining the temperature of the cathode at the predetermined value;
a parameter calculation circuit configured to calculate a determination parameter based on an amount of change in the emission current in a case that the bias voltage is changed; and
an irradiation mechanism configured to irradiate a target object with the electron beam emitted from the thermal electron source,
wherein each of an operation of changing the bias voltage, an operation of measuring the emission current, and an operation of calculating the determination parameter is repeated within a range where the determination parameter does not exceed a threshold value while maintaining the temperature of the cathode at the predetermined value.

According to further another aspect of the present invention, a non-transitory computer-readable storage medium storing a program for causing a computer to execute processing includes:
setting, to a predetermined value, a temperature of a cathode in a thermal electron source having the cathode, an anode electrode controlled to have a positive potential with respect to the cathode, and a Wehnelt electrode arranged between the cathode and the anode electrode and controlled to have a negative potential with respect to the cathode, and emit an electron beam from the cathode to the anode electrode;
changing a bias voltage applied to the Wehnelt electrode while maintaining the temperature of the cathode at the predetermined value;
measuring an emission current in a case that the bias voltage is changed while maintaining the temperature of the cathode at the predetermined value;
storing a measured emission current in a storage device;
reading the emission current from the storage device and calculating a determination parameter based on an amount of change in the emission current in a case that the bias voltage is changed; and
repeating each of the changing of the bias voltage, the measuring of the emission current, and the calculating of the determination parameter within a range where the determination parameter does not exceed a threshold value while maintaining the temperature of the cathode at the predetermined value.

### BRIEF DESCRIPTION OF THE DRAWINGS

FIG. 1 is a conceptual diagram showing the configuration of a writing apparatus according to Embodiment 1;

FIG. 2 is a conceptual diagram showing the configuration of a shaping aperture array substrate in Embodiment 1;

FIG. 3 is a cross-sectional view showing the configuration of a blanking aperture array mechanism in Embodiment 1;

FIG. 4 is a diagram showing an example of the relationship among the emission current, the bias voltage, and the cathode temperature in Embodiment 1;

FIG. 5 is a diagram showing an example of the movement of an operating point in Comparative Example 1 of Embodiment 1;

FIG. 6 is a diagram showing an example of a method for adjusting the operating point in Comparative Example 2 of Embodiment 1;

FIG. 7 is a diagram showing an example of a method for adjusting the operating point in Comparative Example 3 of Embodiment 1;

FIG. 8 is a diagram showing an example of a method for adjusting the operating point in Comparative Example 4 of Embodiment 1;

FIG. 9 is a diagram for explaining the space charge effect in Embodiment 1;

FIG. 10 is a flowchart showing an example of main steps of an electron beam adjustment method in Embodiment 1;

FIG. 11 is a diagram for explaining an example of a method when lowering the cathode temperature in Embodiment 1;

FIG. 12 is a diagram for explaining an example of a method when increasing the cathode temperature in Embodiment 1;

FIG. 13 is a diagram showing an example of a transition of a determination parameter in Embodiment 1;

FIG. 14 is a diagram for explaining the threshold value of the determination parameter when the operating conditions are different and when the cathode design conditions are different in Embodiment 1;

FIG. 15 is a diagram showing an example of an adjustment period in Embodiment 1;

FIG. 16 is a conceptual diagram for explaining an example of a writing operation in Embodiment 1;

FIG. 17 is a diagram showing an example of a multi-beam irradiation region and a writing target pixel in Embodiment 1; and

FIG. 18 is a diagram for explaining an example of a writing method using multiple beams in Embodiment 1.

### DETAILED DESCRIPTION OF THE INVENTION

In the following embodiment, a method and an apparatus are provided that can search for an operating point of a thermal electron source in a path where an electron beam emitted from the thermal electron source does not go deep into the temperature limited region.

In the following embodiment, a configuration using multiple beams as electron beams will be described. However, the invention is not limited to this, and a configuration using a single beam may also be used. In addition, although a writing apparatus will be described below as an example of an electron beam apparatus, any apparatus that uses an electron beam emitted from a thermal-electron emission source, other than the writing apparatus, may be used. For example, an image acquisition apparatus or an inspection apparatus may be used.

### EMBODIMENT 1

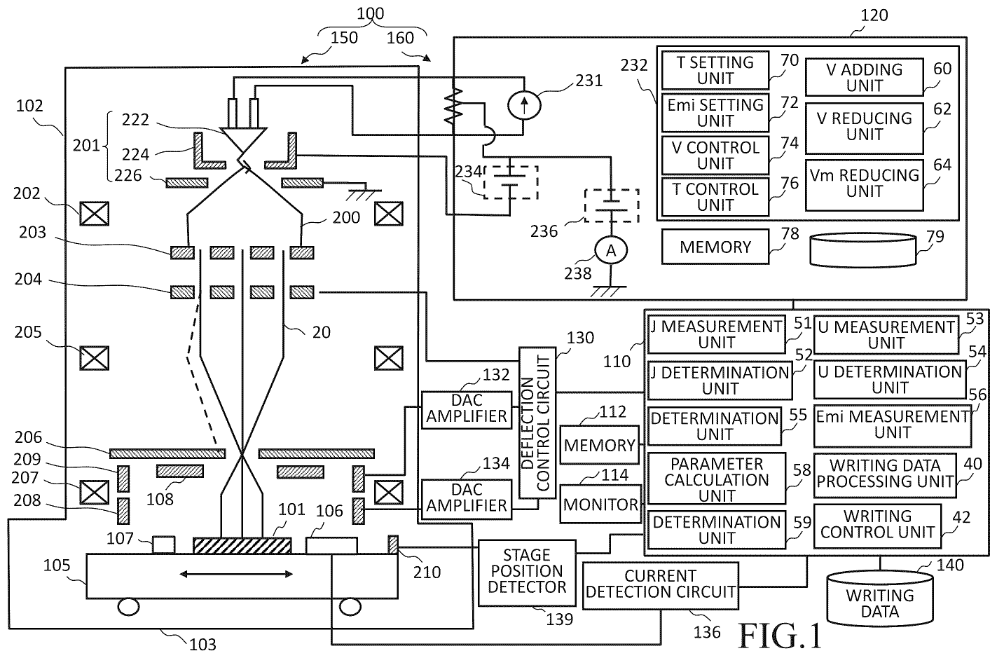

FIG. 1 is a conceptual diagram showing the configuration of a writing apparatus according to Embodiment 1. In FIG. 1, a writing apparatus 100 includes a writing mechanism 150 and a control system circuit 160. The writing apparatus 100 is an example of a multi-electron beam writing apparatus. The writing mechanism 150 (an example of an irradiation mechanism) includes an electron optical column 102 (multi-electron beam column) and a writing chamber 103. An electron emission source 201 (thermal electron source), an illumination lens 202, a shaping aperture array substrate 203, a blanking aperture array mechanism 204, a demagnifying lens 205, a limiting aperture substrate 206, an objective lens 207, a detector 108, a deflector 208, and a deflector 209 are arranged inside the electron optical column 102. An XY stage 105 is arranged in the writing chamber 103. A target object 101 such as a mask blank coated with resist, which serves as a writing target substrate during writing, is arranged on the XY stage 105. The target object 101 includes an exposure mask used in manufacturing semiconductor devices, a semiconductor substrate (silicon wafer) on which a semiconductor device is manufactured, and the like. A mirror 210 for measuring the position of an XY stage 105 is further arranged on the XY stage 105. A Faraday cup 106 is further arranged on the XY stage 105. A mark 107 is further arranged on the XY stage 105.

The electron emission source 201 (thermal electron source, or electron beam emission source) has a cathode 222, a Wehnelt 224 (Wehnelt electrode), and an anode 226 (anode electrode). In addition, the anode 226 is grounded. The anode 226 is controlled to have a positive potential with respect to the cathode 222. The Wehnelt 224 is controlled to have a negative potential with respect to the cathode 222. The electron emission source 201 emits an electron beam 200 from the cathode 222 toward the anode 226.

The control system circuit 160 includes a control calculator 110, a memory 112, a monitor 114, an electron emission source power supply device 120, a deflection control circuit 130, digital-to-analog conversion (DAC) amplifier units 132 and 134, a current detection circuit 136, a stage position detector 139, and a storage device 140 such as a magnetic disk drive. The control calculator 110, the memory 112, the monitor 114, the electron emission source power supply device 120, the deflection control circuit 130, the DAC amplifier units 132 and 134, the current detection circuit 136, the stage position detector 139, and storage device 140 are connected to each other through a bus (not shown). The DAC amplifier units 132 and 134 and the blanking aperture array mechanism 204 are connected to the deflection control circuit 130. The output of the DAC amplifier unit 132 is connected to the deflector 209. The output of the DAC amplifier unit 134 is connected to the deflector 208. The deflector 208 is formed by electrodes having four or more poles, and each electrode is controlled by the deflection control circuit 130 through the DAC amplifier 134. The deflector 209 is formed by electrodes having four or more poles, and each electrode is controlled by the deflection control circuit 130 through the DAC amplifier 132. The stage position detector 139 irradiates a mirror 210 on the XY stage 105 with laser light and receives reflected light from the mirror 210. Then, the position of the XY stage 105 is measured by using the principle of laser interference using information on the reflected light. The output of the Faraday cup 106 is connected to the current detection circuit 136.

The control calculator 110 includes a current density measurement unit 51, a current density determination unit 52, a current density distribution measurement unit 53, a current density distribution determination unit 54, a determination unit 55, an emission current measurement unit 56, a parameter calculation unit 58, a determination unit 59, a writing data processing unit 40, and a writing control unit 42. Each “˜ unit”, such as the current density measurement unit 51, the current density determination unit 52, the current density distribution measurement unit 53, the current density distribution determination unit 54, the determination unit 55, the emission current measurement unit 56, the parameter calculation unit 58, the determination unit 59, the writing data processing unit 40, and the writing control unit 42, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the current density measurement unit 51, the current density determination unit 52, the current density distribution measurement unit 53, the current density distribution determination unit 54, the determination unit 55, the emission current measurement unit 56, the parameter calculation unit 58, the determination unit 59, the writing data processing unit 40, and the writing control unit 42 and information being calculated are stored in the memory 112 each time.

The electron emission source power supply device 120 includes a control calculator 232, a memory 78, a storage device 79 such as a magnetic disk drive, an acceleration voltage power supply circuit 236, a bias voltage power supply circuit 234, a filament power supply circuit 231 (filament power supply unit), and an ammeter 238. The memory 78, the storage device 79, the acceleration voltage power supply circuit 236, the bias voltage power supply circuit 234, the filament power supply circuit 231, and the ammeter 238 are connected to the control calculator 232 through a bus (not shown).

A bias voltage adding unit 60, a bias voltage reducing unit 62, a bias voltage margin reducing unit 64, a cathode temperature setting unit 70, an emission current setting unit 72, a bias voltage control unit 74, and a cathode temperature control unit 76 are arranged inside the control calculator 232. Each “˜ unit”, such as the bias voltage adding unit 60, the bias voltage reducing unit 62, the bias voltage margin reducing unit 64, the cathode temperature setting unit 70, the emission current setting unit 72, the bias voltage control unit 74, and the cathode temperature control unit 76 has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the bias voltage adding unit 60, the bias voltage reducing unit 62, the bias voltage margin reducing unit 64, the cathode temperature setting unit 70, the emission current setting unit 72, the bias voltage control unit 74, and the cathode temperature control unit 76 and information being calculated are stored in the memory 78 each time.

The negative (−) side of the acceleration voltage power supply circuit 236 is connected to both poles of the cathode 222 in the electron optical column 102. The anode (+) side of the acceleration voltage power supply circuit 236 is grounded through the ammeter 238 connected in series. In addition, the cathode (−) of the acceleration voltage power supply circuit 236 is also branched and connected to the anode (+) of the bias voltage power supply circuit 234. The cathode (−) of the bias voltage power supply circuit 234 is electrically connected to the Wehnelt 224 arranged between the cathode 222 and the anode 226. In other words, the bias voltage power supply circuit 234 is arranged so as to be electrically connected between the cathode (−) of the acceleration voltage power supply circuit 236 and the Wehnelt 224. Then, the filament power supply circuit 231 controlled by the cathode temperature control unit 76 makes a current flow between the two poles of the cathode 222 to heat the cathode 222 to a predetermined temperature. In other words, the filament power supply circuit 231 supplies filament power W to the cathode 222. The filament power W and the cathode temperature T can be defined in a predetermined relationship, and the cathode temperature T can be heated to a desired cathode temperature T by the filament power W. Therefore, the cathode temperature T is controlled by the filament power W. The filament power W is defined as a product of the current flowing between the two poles of the cathode 222 and the voltage applied between the two poles of the cathode 222 by the filament power supply circuit 231. The acceleration voltage power supply circuit 236 applies an acceleration voltage between the cathode 222 and the anode 226. The bias voltage power supply circuit 234 controlled by the bias voltage control unit 74 applies a negative bias voltage to the Wehnelt 224.

In addition, writing data is input from outside the writing apparatus 100 and stored in the storage device 140. The writing data usually defines information on a plurality of figures to be written. Specifically, for each figure, for example, the coordinates of the vertices that make up the figure are defined in the order in which the figure is formed. Alternatively, for each figure, for example, a figure code, reference position coordinates, and a size are defined.

Here, FIG. 1 describes components necessary for explaining Embodiment 1. The writing apparatus 100 may also include other components that are normally required.

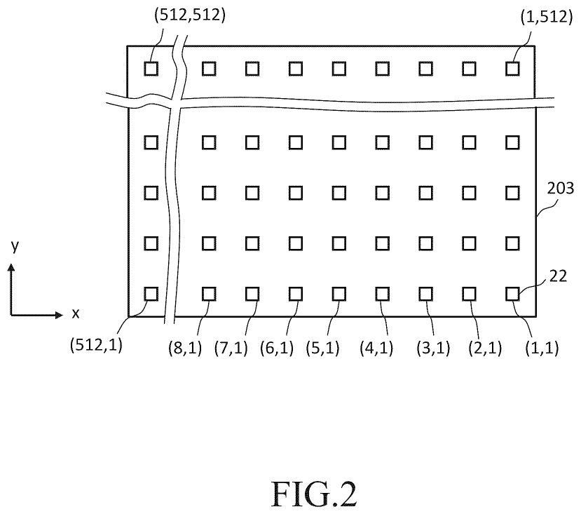

FIG. 2 is a conceptual diagram showing the configuration of a shaping aperture array substrate 203 in Embodiment 1. In FIG. 2, in the shaping aperture array substrate 203, holes (openings) 22 are formed in a matrix of p rows wide (in the x direction)×q columns long (in the y direction) (p, q>2) at predetermined arrangement pitches. In FIG. 2, for example, 512×512 holes 22 are formed in length and width directions (x and y directions). The holes 22 are formed in rectangles having the same dimension and shape. Alternatively, the holes 22 may be circles having the same diameter. The shaping aperture array substrate 203 (beam forming mechanism) forms multiple beams 20. Specifically, some of electron beams 200 pass through the plurality of holes 22 to form multiple beams 20. In addition, the arrangement of the holes 22 is not limited to the case where the holes 22 are arranged in a lattice pattern in length and width directions as shown in FIG. 2. For example, holes in the k-th column and the (k+1)-th column in the length direction (y direction) may be arranged so as to be shifted from each other by a dimension a in the width direction (x direction). Similarly, holes in the (k+1)-th column and the (k+2)-th column in the length direction (y direction) may be arranged so as to be shifted from each other by a dimension b in the width direction (x direction).

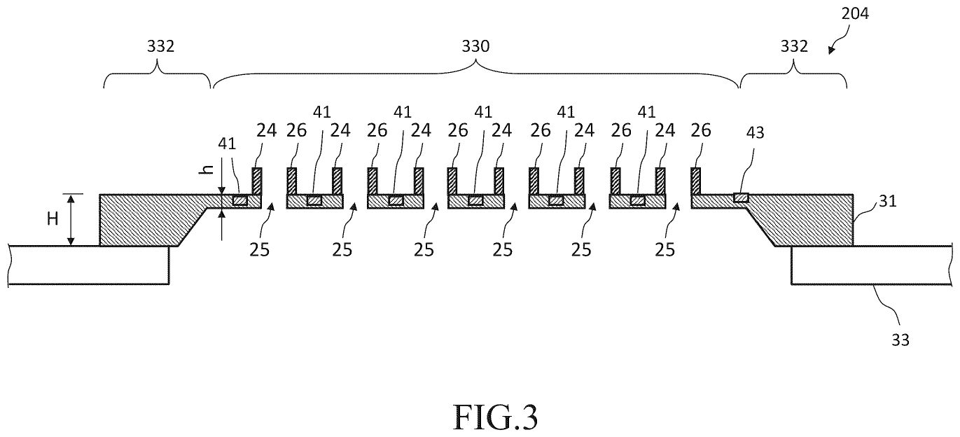

FIG. 3 is a cross-sectional view showing the configuration of a blanking aperture array mechanism 204 in Embodiment 1. In the blanking aperture array mechanism 204, as shown in FIG. 3, a semiconductor substrate 31 formed of silicon or the like is arranged on a support base 33. The central portion of the substrate 31 is cut from, for example, the back surface side and processed into a membrane region 330 (first region) having a small film thickness h. A periphery surrounding the membrane region 330 is an outer peripheral region 332 (second region) having a large film thickness H. The upper surface of the membrane region 330 and the upper surface of the outer peripheral region 332 are formed so as to be at the same height position or substantially the same height position. The substrate 31 is supported on the support base 33 at the back surface of the outer peripheral region 332. The central portion of the support base 33 is open, and the membrane region 330 is located in the open region of the support base 33.

In the membrane region 330, a passage hole 25 (opening) through which each of the multiple beams 20 passes is opened at a position corresponding to each hole 22 in the shaping aperture array substrate 203 shown in FIG. 2. In other words, a plurality of passage holes 25 through which the corresponding beams of the multiple beams 20 using electron beams pass are formed in an array in the membrane region 330 of the substrate 31. Then, a plurality of electrode pairs each having two electrodes are arranged at positions facing each other with the corresponding passage hole 25, among the plurality of passage holes 25, interposed therebetween, on the membrane region 330 of the substrate 31. Specifically, on the membrane region 330, as shown in FIG. 3, a pair of a control electrode 24 for blanking deflection and a counter electrode 26 (blanker: blanking deflector) are arranged with the passage hole 25 corresponding to the vicinity of each through hole 25 interposed therebetween. In addition, inside the substrate 31 and in the vicinity of each passage hole 25 on the membrane region 330, a control circuit 41 (logic circuit) for applying a deflection voltage to the control electrode 24 for each passage hole 25 is arranged. The counter electrode 26 for each beam is grounded.

In the control circuit 41, for example, an amplifier (not shown; an example of a switching circuit) such as a CMOS inverter circuit is arranged. The output line (OUT) of the amplifier is connected to the control electrode 24. On the other hand, a ground potential is applied to the counter electrode 26. Either an L (low) potential (for example, ground potential) that is lower than the threshold voltage or an H (high) potential (for example, 1.5 V) that is equal to or higher than the threshold voltage is applied to the input (IN) of the amplifier as a control signal. In Embodiment 1, in a state in which the L potential is applied to the input (IN) of the amplifier, the output (OUT) of the amplifier becomes a positive potential (Vdd). Therefore, since the corresponding beam is deflected by an electric field due to the potential difference from the ground potential of the counter electrode 26 and blocked by the limiting aperture substrate 206, the beam is controlled to be turned off. On the other hand, in a state in which the H potential is applied to the input (IN) of the amplifier (active state), the output (OUT) of the amplifier has a ground potential, and there is no potential difference from the ground potential of the counter electrode 26. Therefore, since the corresponding beam is not deflected, the beam passes through the limiting aperture substrate 206. In this manner, the beam is controlled to be turned on.

The pairs of control electrodes 24 and counter electrodes 26 individually perform blanking deflection of the corresponding beams of the multiple beams 20 by the potentials switched by the amplifiers serving as the corresponding switching circuits. In this manner, a plurality of blankers perform blanking deflection on the corresponding beams, among the multiple beams 20 that have passed through the plurality of holes 22 (openings) in the shaping aperture array substrate 203.

Next, the operation of the writing mechanism 150 in the writing apparatus 100 will be described. The electron beam 200 emitted from the electron emission source 201 illuminates the entire shaping aperture array substrate 203 through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, a plurality of rectangular electron beams (multiple beams 20). The multiple beams 20 pass through corresponding blankers (first deflectors: individual blanking mechanisms) of the blanking aperture array mechanism 204. Each of these blankers individually deflects the electron beam passing therethrough (performs blanking deflection).

The multiple beams 20 that have passed through the blanking aperture array mechanism 204 are reduced by the demagnifying lens 205 and travel toward a central hole formed in the limiting aperture substrate 206. Here, among the multiple beams 20, the electron beam deflected by the blanker of the blanking aperture array mechanism 204 is shifted from the central hole in the limiting aperture substrate 206 and is blocked by the limiting aperture substrate 206. On the other hand, the electron beam that is not deflected by the blanker of the blanking aperture array mechanism 204 passes through the central hole of the limiting aperture substrate 206 as shown in FIG. 1. By turning on/off such individual blanking mechanisms, blanking control is performed, and beam on/off is controlled. Then, for each beam, by the beam that has passed through the limiting aperture substrate 206 and is formed from the beam ON state to the beam OFF state, each beam of one shot is formed. The multiple beams 20 that have passed through the limiting aperture substrate 206 are focused by the objective lens 207 to become a pattern image having a desired reduction ratio, and respective beams (all of the multiple beams 20) that have passed through the limiting aperture substrate 206 are collectively deflected in the same direction by the deflectors 208 and 209 and emitted to the respective irradiation positions of the beams on the target object 101. The multiple beams 20 emitted at one time are ideally arranged at a pitch obtained by multiplying the arrangement pitch of the plurality of holes 22 of the shaping aperture array substrate 203 by the desired reduction ratio described above.

As described above, in the electron emission source that emits an electron beam, in order to obtain the desired emission current at the lowest possible cathode temperature, the operating point of the thermal electron source is often set near the boundary between the space charge limited region and the temperature limited region, but not within the temperature limited region.

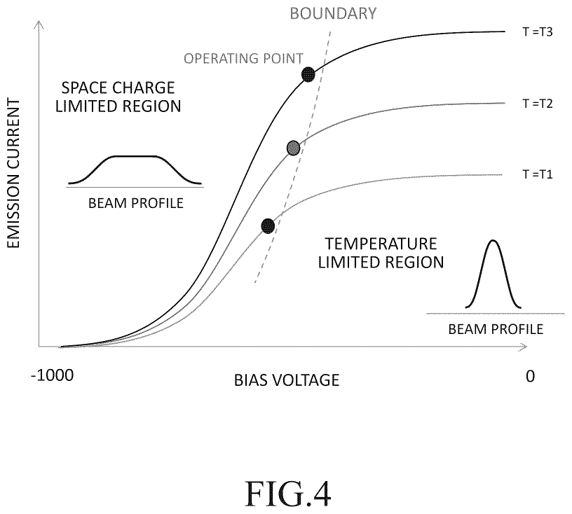

FIG. 4 is a diagram showing an example of the relationship among the emission current, the bias voltage, and the cathode temperature in Embodiment 1. The vertical axis indicates the emission current, and the horizontal axis indicates the bias voltage. FIG. 4 shows characteristic curves of the emission current and the bias voltage for each cathode temperature. The cathode temperatures T have a relationship of T3>T2>T1. The boundary between the space charge limited region and the temperature limited region is shown by the dotted line. The bias voltage value at the boundary between the space charge limited region and the temperature limited region changes with the cathode temperature. In general, the lower the cathode temperature, the smaller the bias voltage as a boundary becomes on the negative side. Then, the operating point for driving the electron emission source 201 is set near the boundary between the space charge limited region and the temperature limited region, but not within the temperature limited region.

When an electron beam is emitted in the temperature limited region, the current density distribution of the beam has a steep shape with low uniformity, and there are portions with locally high intensity in the current density distribution of the beam. On the other hand, when an electron beam is emitted in the space charge limited region, the current density distribution of the beam has a highly uniform shape. For the same emission current, the locally high intensity in the current density distribution of the beam in the temperature limited region is higher than the intensity of the uniform portion in the current density distribution of the beam in the space charge limited region. In addition, the locally high intensity in the current density distribution of the beam in the temperature limited region when the emission current is small may be higher than the intensity of the uniform portion in the current density distribution of the beam in the space charge limited region when the emission current is large. For this reason, there has been a problem in that, when an electron beam is emitted in the temperature limited region, the aperture substrate and the like struck by the electron beam may be damaged. For this reason, it is required to search for the operating point in a path that does not go deep into the temperature limited region.

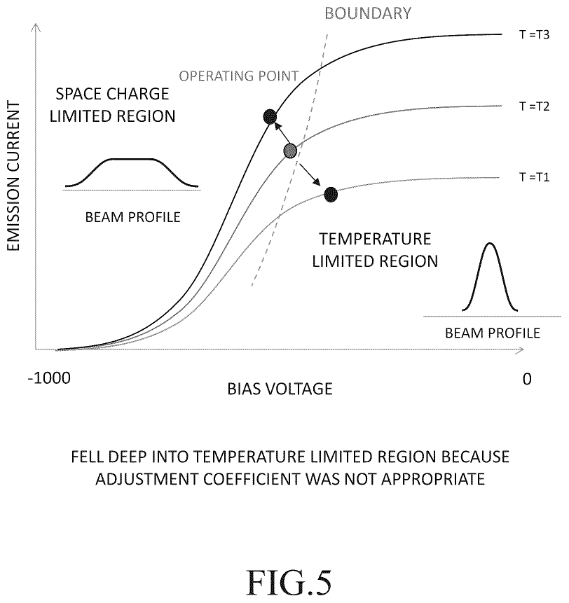

FIG. 5 is a diagram showing an example of the movement of the operating point in Comparative Example 1 of Embodiment 1. The characteristic curves in FIG. 5 are similar to those in FIG. 4. For example, when changing the cathode temperature from the operating point of the cathode temperature T2, if there is an error in acquiring the coefficients for automatic adjustment in the cathode operating temperature adjustment method described in Japanese Patent No. 6166910, an adjustment other than the intended one may be made. For example, as shown in FIG. 5, when the operating point of the cathode temperature T2 is lowered to the cathode temperature T1, the cathode operating condition (operating point) may fall deep into the temperature limited region. In order to avoid such a phenomenon, even if limits are set on the emission current value or the bias voltage value, this is still not a 100% solution.

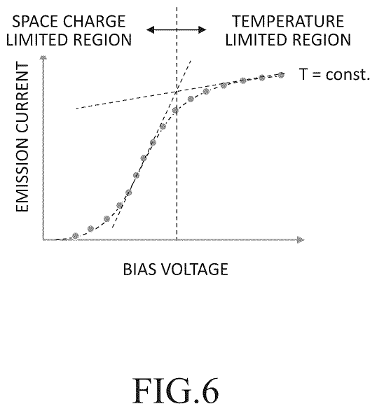

FIG. 6 is a diagram showing an example of a method for adjusting the operating point in Comparative Example 2 of Embodiment 1. In FIG. 6, the vertical axis indicates the emission current, and the horizontal axis indicates the bias voltage. In the example of FIG. 6, an example of a method for measuring the relationship between the emission current and the bias voltage for each cathode temperature until the bias saturation point is reached and determining the operating point from the characteristics is shown. In the method of FIG. 6, the characteristics of the emission current and the bias voltage are measured with the temperature kept constant, and the intersection of the straight lines obtained from the points on the low bias voltage side and the points on the high bias voltage side is defined as the boundary between the temperature limited region and the space charge limited region. However, in such a method, data should be measured over a wide range up to the deep part of the temperature limited region. In addition, it is difficult to draw a straight line. In particular, there has been a problem in that the calculation error of the boundary between the temperature limited region and the space charge limited region increases in the method of defining the straight line on the space charge limited region side.

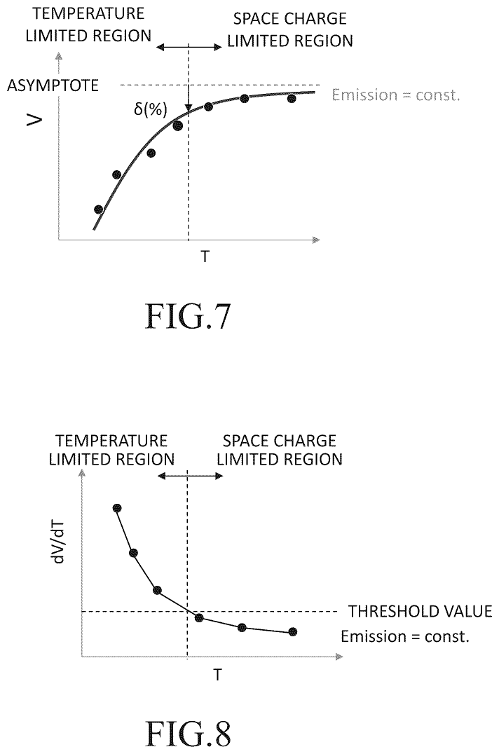

FIG. 7 is a diagram showing an example of a method for adjusting the operating point in Comparative Example 3 of Embodiment 1. In FIG. 7, the vertical axis indicates the bias voltage V, and the horizontal axis indicates the cathode temperature T. In the method of FIG. 7, the bias voltage V is measured while changing the temperature with the emission current kept constant. The measurement points are fitted with an appropriate function, and the region where σ drops from the asymptote of the fitting curve is defined as the temperature limited region and the space charge limited region.

FIG. 8 is a diagram showing an example of a method for adjusting the operating point in Comparative Example 4 of Embodiment 1. In FIG. 8, the vertical axis indicates the amount of change dV in the bias voltage V with respect to the amount of change dT in the cathode temperature T, and the horizontal axis indicates the cathode temperature T. In the method of FIG. 8, the amount of change (dV/dT) in the bias voltage V is calculated while changing the cathode temperature T with the emission current kept constant. Then, a point where the value of dV/dT reaches a predetermined threshold value is defined as the boundary between the temperature limited region and the space charge limited region.

In this manner, in the methods shown in FIGS. 7 and 8, the bias voltage V for maintaining the emission current constant is measured each time while changing the cathode temperature, and a position where the amount of change in the bias voltage V is sufficiently small relative to the amount of change in the cathode temperature T is searched for as the operating point. In any of these methods, it is necessary to measure data over a wide range up to the deep part of the temperature limited region in the process of obtaining the operating point.

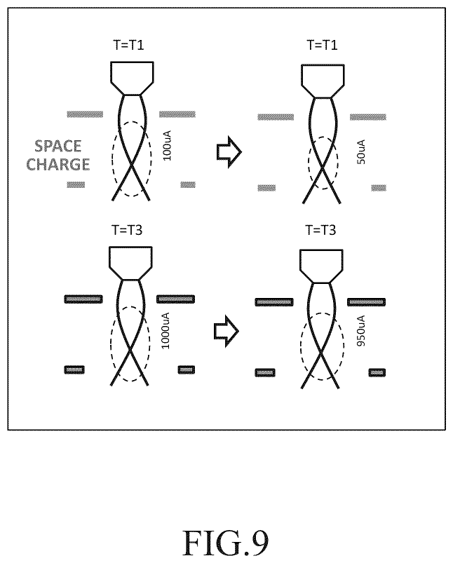

FIG. 9 is a diagram for explaining the space charge effect in Embodiment 1. The space charge effect is created by the emission current itself. Here, in order to make the explanation easier to understand, it is assumed herein that if the emission current is halved, the space charge effect is also halved. As shown in the upper diagram of FIG. 9, when the electron emission source is driven with an emission current of, for example, 100 μA at a cathode temperature T1, the space charge effect decreases significantly if the emission current is changed to 50 μA. On the other hand, as shown in the lower diagram of FIG. 9, when the electron emission source is driven with an emission current of, for example, 1000 μA at a cathode temperature T3, the space charge effect does not decrease significantly even if the emission current decreases by 50 μA. Thus, the strength of the space charge effect changes with the rate of change in the emission current, not with the amount of change. In Embodiment 1, the operating point is adjusted by taking into consideration the strength of the space charge effect. Hereinafter, a specific description will be given.

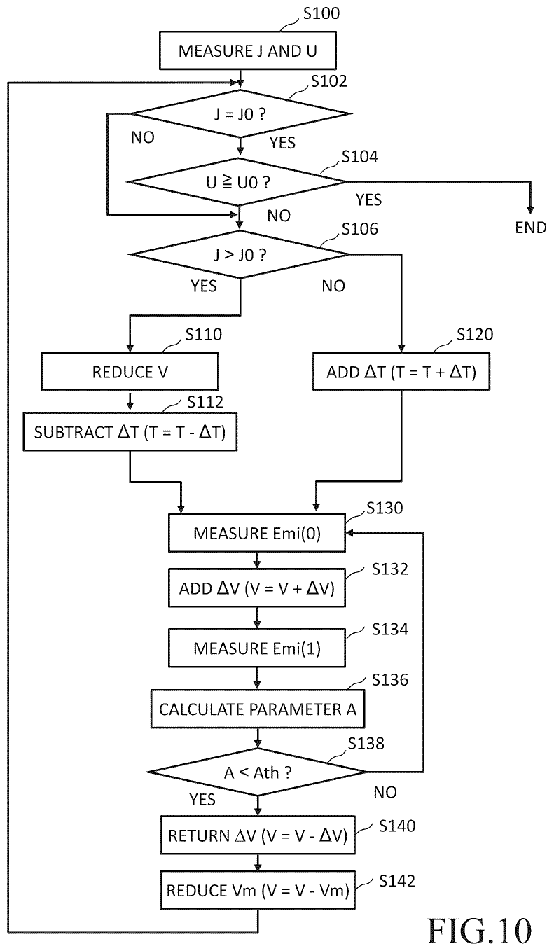

FIG. 10 is a flowchart showing an example of main steps of a method for adjusting an electron beam in Embodiment 1. In FIG. 10, a series of steps, that is, a current density and current density distribution measurement step (S100), a current density determination step (S102), a current density distribution determination step (S104), a determination step (S106), a bias voltage reduction step (S110), a cathode temperature reduction step (S112), a cathode temperature adding step (S120), an emission current measurement step (S130), a bias voltage adding step (S132), an emission current measurement step (S134), a parameter calculation step (S136), a determination step (S138), a bias voltage return step (S140), and a bias voltage margin reduction step (S142), are executed.

In the current density and current density distribution measurement step (S100), the current density measurement unit 51 measures the current density J of the multiple beams 20 reaching the target object 101. First, the XY stage 105 is moved to a position where the multiple beams 20 can be incident on the Faraday cup 106. Then, the total current value of the multiple beams 20 formed from the electron beam 200 emitted from the electron emission source 201 and reaching the target object surface position is detected by the Faraday cup 106. The signal detected by the Faraday cup 106 is output to the current detection circuit 136, converted into digital data, and output to the control calculator 110. In the control calculator 110, the current density measurement unit 51 calculates the total current density J of the multiple beams 20. The current density J can be calculated by dividing the measured current value by the total opening area of the plurality of holes 22 in the shaping aperture array substrate 203.

In addition, the current density distribution measurement unit 53 measures the current density distribution U of the multiple beams 20 reaching the target object 101. The multiple beams 20 is divided into a plurality of beam array groups, and the current value of each beam array group is detected by the Faraday cup 106. Beams other than the target beam array group may be turned off by the blanking aperture array mechanism 204. The signal detected by the Faraday cup 106 is output to the current detection circuit 136, converted into digital data, and output to the control calculator 110. In the control calculator 110, the current density distribution measurement unit 53 calculates a current density j for each beam array group. The current density j can be calculated by dividing the measured current value by the total opening area of the plurality of holes 22 for each beam array group of the shaping aperture array substrate 203. The current density distribution measurement unit 53 calculates the current density distribution U using the current density j for each beam array group.

The current density measurement unit 51 may calculate the total current density J of the multiple beams 20 by summing up the current densities j for each beam array group.

When the apparatus is started up, the cathode temperature setting unit 70 sets a preset initial value for the cathode temperature, and the emission current setting unit 72 sets a preset initial value for the emission current. The bias voltage V is set to a sufficiently small value (a value on the negative side). Adjustment may be started from this state. The bias voltage V can start from the space charge limited region by starting from a sufficiently small value on the negative side.

In the current density determination step (S102), the current density determination unit 52 determines whether or not the measured total current density J of the multiple beams 20 is a desired current density J0 or whether or not the measured current density J of the entire multiple beams 20 falls within an acceptable range centered on the desired current density J0. When the current density J is the desired current density J0 or falls within the allowable range centered on the desired current density J0, the process proceeds to the current density distribution determination step (S104). When the current density J is not the desired current density J0 or does not fall within the allowable range centered on the desired current density J0, the process proceeds to the determination step (S106).

In the current density distribution determination step (S104), the current density distribution determination unit 54 determines whether or not the uniformity of the measured current density distribution U is equal to or greater than a desired uniformity U0. When the uniformity of the current density distribution U is equal to or greater than the desired uniformity U0, no beam adjustment is required. Therefore, the adjustment of the electron beam ends. When the uniformity of the current density distribution U is not equal to or greater than the desired uniformity U0, the process proceeds to the determination step (S106).

In the determination step (S106), the determination unit 55 determines whether or not the measured total current density J of the multiple beams 20 is greater than the desired current density J0. The current density J is increased by increasing the emission current Emi. Conversely, the current density J is reduced by reducing the emission current Emi. It is desirable to operate the electron emission source 201 at the lowest possible cathode temperature T at which an emission current Emi for obtaining the desired current density J0 can be obtained. Therefore, when the current density J is greater than the desired current density J0, the cathode temperature T is lowered. Conversely, when the current density J is smaller than the desired current density J0, the emission current Emi is insufficient, so that the cathode temperature T is increased. The determination to do so is made herein. When the current density J is greater than the desired current density J0, the process proceeds to the bias voltage reduction step (S110). When the current density J is not greater than the desired current density J0 (here, when the current density J is smaller than the desired current density J0), the process proceeds to the cathode temperature adding step (S120).

In the bias voltage reduction step (S110), the bias voltage control unit 74 controls the bias voltage power supply circuit 234 to sufficiently reduce the current bias voltage V.

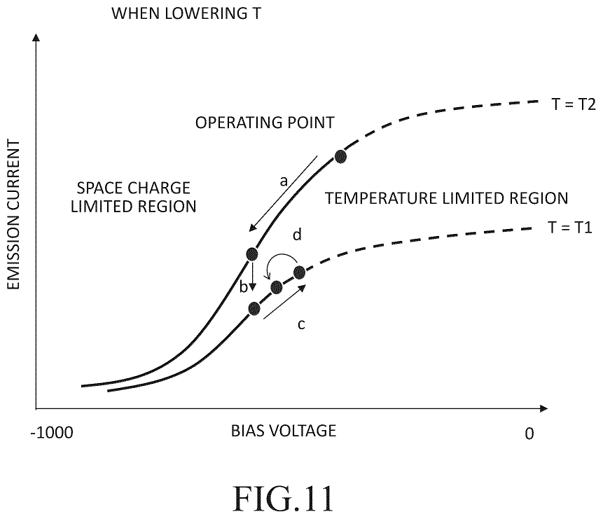

FIG. 11 is a diagram for explaining an example of a method when lowering the cathode temperature in Embodiment 1. In FIG. 11, the vertical axis indicates the emission current, and the horizontal axis indicates the bias voltage. In the example of FIG. 11, a characteristic curve of the emission current and bias voltage at the cathode temperature T2 and a characteristic curve of the emission current and bias voltage at the cathode temperature T1 are shown. In the characteristic curves, the solid line indicates the space charge limited region and the dotted line indicates the temperature limited region. T2>T1. If the cathode temperature is lowered from T2 to T1 while maintaining the bias voltage as it is in a state of driving at the operating point where the cathode temperature is T2, the operating point falls within the temperature limited region. Therefore, before lowering the cathode temperature, the bias voltage control unit 74 reduces the bias voltage to the negative side by a value sufficient to maintain the operating point in the space charge limited region even if the cathode temperature is lowered from T2 to T1 (operation a in FIG. 11). The sufficient value may be set empirically.

In the cathode temperature reduction step (S112), the cathode temperature setting unit 70 (temperature setting unit) sets the temperature of the cathode 222 to a predetermined value. Specifically, the operation is as follows. The cathode temperature setting unit 70 subtracts ΔT from the current cathode temperature T, and sets the cathode temperature lowered by ΔT from the current cathode temperature T as a new cathode temperature T. The cathode temperature control unit 76 controls the filament power supply circuit 231 so that the set cathode temperature T is obtained. As a result, the cathode temperature is controlled to become a newly set cathode temperature T that has been lowered by ΔT (operation b in FIG. 11). It is preferable that ΔT is set in the range of 5 to 50° C., for example. For example, ΔT is set to 10° C.

In the cathode temperature adding step (S120), the cathode temperature setting unit 70 sets the temperature of the cathode 222 to a predetermined value. Specifically, the operation is as follows. The cathode temperature setting unit 70 adds ΔT to the current cathode temperature T, and sets the cathode temperature increased by ΔT from the current cathode temperature T as a new cathode temperature T. The cathode temperature control unit 76 controls the filament power supply circuit 231 so that the set cathode temperature T is obtained. As a result, the cathode temperature is controlled to become a newly set cathode temperature T which is higher by ΔT. As shown in FIG. 4, even if the cathode temperature T is increased while the bias voltage is maintained as it is, the operating point does not fall within the temperature limited region, so that the space charge limited region can be maintained.

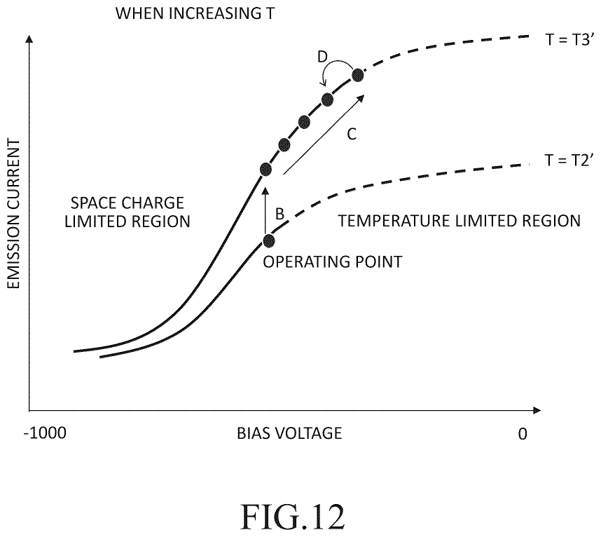

FIG. 12 is a diagram for explaining an example of a method when increasing the cathode temperature in Embodiment 1. In FIG. 12, the vertical axis indicates the emission current, and the horizontal axis indicates the bias voltage. In the example of FIG. 12, a characteristic curve of the emission current and bias voltage at a cathode temperature T2′ and a characteristic curve of the emission current and bias voltage at a cathode temperature T3′ are shown. In the characteristic curves, the solid line indicates the space charge limited region and the dotted line indicates the temperature limited region. T3′>T2 ‘. Even if the cathode temperature is increased from T2’ to T3′ while maintaining the bias voltage as it is in a state of driving at the operating point where the cathode temperature is T2′, the operating point does not fall within the temperature limited region. Therefore, the cathode temperature setting unit 70 sets, as a new cathode temperature T, a cathode temperature increased by ΔT from the current cathode temperature T while maintaining the current bias voltage (operation B in FIG. 12).

In the emission current measurement step (S130), the emission current measurement unit 56 measures the current emission current Emi(0). The value of the emission current Emi can be obtained as a current value detected by the ammeter 238. The obtained emission current Emi(0) is stored in the storage device 140 or the like.

In the bias voltage adding step (S132), the bias voltage control unit 74 changes the bias voltage V applied to the Wehnelt 224 while maintaining the temperature T of the cathode at a set predetermined value. Specifically, the operation is as follows. First, the bias voltage adding unit 60 sets, as a new bias voltage V, a bias voltage obtained by adding ΔV to the current bias voltage V (for example, operation c in FIG. 11 or operation C in FIG. 12). The bias voltage control unit 74 applies the new bias voltage V to the Wehnelt 224.

Here, the bias voltage V indicates a potential difference between the negative potential applied to the cathode 222 and the negative potential applied to the Wehnelt 224. For example, 10 to 50 V may be used as ΔV. For example, 20 V is used.

In the emission current measurement step (S134), the emission current measurement unit 56 measures an emission current Emi(1) when the bias voltage V is changed while maintaining the cathode temperature T at a set predetermined value. The value of the emission current Emi can be obtained as a current value detected by the ammeter 238. The obtained emission current Emi(1) is stored in the storage device 140 or the like.

In the parameter calculation step (S136), the parameter calculation unit 58 calculates a determination parameter A based on the amount of change in the emission current when the bias voltage V is changed. In other words, the parameter calculation unit 58 calculates, as the determination parameter A, a value obtained by dividing the rate of change in the emission current when the bias voltage V is changed by the amount of change ΔV in the bias voltage. The rate of change ΔE (%) in the emission current can be defined by the following Equation (1), which divides the amount of change ΔEmi in the emission current by the emission current Emi(0) before the change.

$$Δ E ( \% ) = ( Emi ( 1 ) - Emi ( 0 ) ) / Emi ( 0 ) = Δ Emi / Emi ( 0 ) \qquad ( 2 )$$

The determination parameter A can be defined by the following Equation (2).

$$A = Δ E ( \% ) / Δ V = ( Δ Emi / Emi ( 0 ) ) / ΔV = ( ( Emi ( 1 ) - Emi ( 0 ) ) / Emi ( 0 ) ) / Δ V \qquad ( 2 )$$

In the determination step (S138), the determination unit 59 compares the determination parameter A with a threshold value Ath. Specifically, it is determined whether or not the determination parameter A is smaller than the threshold value Ath. When the determination parameter A is smaller than the threshold value Ath, the process proceeds to the bias voltage return step (S140). When the determination parameter A is not smaller than the threshold value Ath, the process returns to the emission current measurement step (S130) to repeat the steps from the emission current measurement step (S130) to the determination step (S138) until the determination parameter A becomes smaller than the threshold value Ath. In other words, while maintaining the cathode temperature T at a predetermined value, the step of changing the bias voltage V, the step of measuring the emission current, and the step of calculating the determination parameter A are repeated within a range in which the determination parameter A does not exceed the threshold value Ath. For example, while maintaining the cathode temperature T at a predetermined value, the step of changing the bias voltage V, the step of measuring the emission current, and the step of calculating the determination parameter A are repeated until the determination parameter A reaches the threshold value Ath (for example, operation c in FIG. 11 or operation C in FIG. 12).

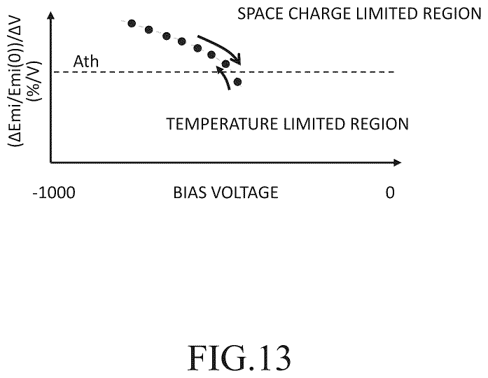

FIG. 13 is a diagram showing an example of the transition of a determination parameter in Embodiment 1. In FIG. 13, the vertical axis indicates the determination parameter A, and the horizontal axis indicates the bias voltage. In Embodiment 1, the step of changing the bias voltage V, the step of measuring the emission current, and the step of calculating the determination parameter A are repeated so that the determination parameter A approaches the threshold value Ath from a state in which the determination parameter A is greater than the threshold value Ath. Therefore, it is possible to prevent the determination parameter A from falling within the temperature limited region until the determination parameter A reaches the threshold value Ath.

As the threshold value Ath, a value of 0.5 to 0.9 is used. For example, Ath=0.9 is used.

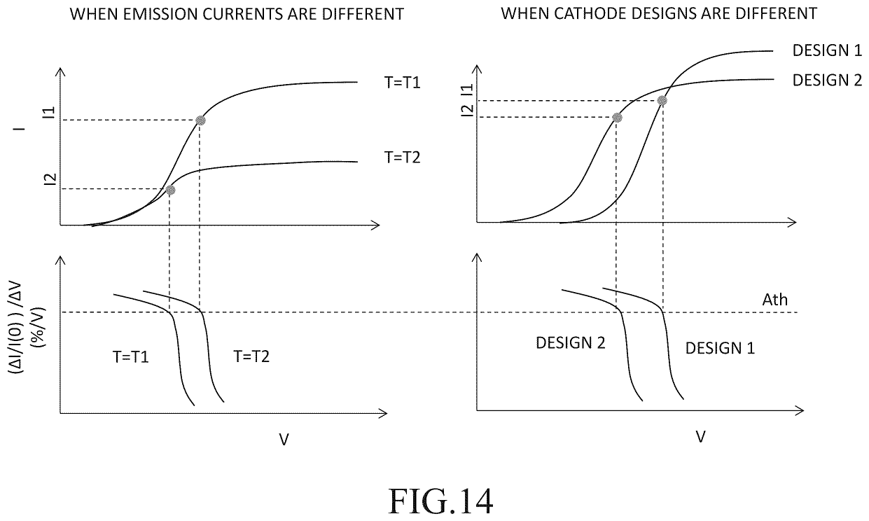

FIG. 14 is a diagram for explaining the threshold value of a determination parameter when the operating conditions are different and when the cathode design conditions are different in Embodiment 1. FIG. 14 shows a case where a VI characteristic curve of the bias voltage V and the emission current I is converted into a VA characteristic curve of the bias voltage V and the determination parameter A obtained by dividing the rate of change ΔE (%) in the emission current by the amount of change ΔV in the bias voltage.

The left diagram of FIG. 14 shows a case where the emission current differs at the boundary position between the space charge limited region and the temperature limited region. The emission current I1 at the boundary position is obtained at the cathode temperature T1. The emission current I2 at the boundary position is obtained at the cathode temperature T2. Then, bias voltages for obtaining these emission currents are different. When such a VI characteristic curve is converted into a VA characteristic curve, it can be seen that the determination parameter A of the inflection point corresponding to the boundary position between the space charge limited region and the temperature limited region shows the same value for the cathode temperature T1 and cathode temperature T2.

The right diagram of FIG. 14 shows different designs of the cathode 222. The emission current I1 at the boundary position between the space charge limited region and the temperature limited region is obtained by Design 1. The emission current I2 at the boundary position is obtained by Design 2. Then, bias voltages for obtaining these emission currents are different. When such a VI characteristic curve is converted into a VA characteristic curve, it can be seen that the determination parameter A of the inflection point corresponding to the boundary position between the space charge limited region and the temperature limited region shows the same value for Design 1 and Design 2. In addition, it can be seen that these values are the same as those shown in the left diagram of FIG. 14.

The value of the inflection point may be set as the threshold value Ath. In other words, the cathode 222 behaves in the same manner regardless of design conditions such as the dimensions of the cathode 222, changes in characteristics due to wear of the cathode 222, and operating conditions of the cathode 222. Therefore, this shows that the determination parameter can be compared and determined using the same criteria (the same threshold value Ath) regardless of the design conditions such as the dimensions of the cathode 222, the changes in characteristics due to wear of the cathode 222, and the operating conditions of the cathode 222.

In the bias voltage return step (S140), when the determination parameter A reaches the threshold value Ath, the bias voltage reduction unit 62 subtracts ΔV from the bias voltage V at that time to return the bias voltage V to the previous state. The bias voltage control unit 74 applies a new bias voltage V to the Wehnelt 224 (for example, operation d in FIG. 11 or operation D in FIG. 12). As a result, the determination parameter A returns from a state shallowly inside the temperature limited region to the space charge limited region side near the boundary position. In other words, the operation of the electron emission source 201 returns from an operation at a position shallowly inside the temperature limited region to an operation in the space charge limited region near the boundary position. In Embodiment 1, since the operation is performed so that the determination parameter A approaches the threshold value Ath (boundary between the space charge limited region and the temperature limited region) from a state in which the determination parameter A is greater than the threshold value Ath (space charge limited region), it is possible to avoid going deep into the temperature limited region.

In the bias voltage margin reduction step (S142), the bias voltage margin reducing unit 64 reduces the bias voltage to the negative side by a width set in advance when the determination parameter A reaches the threshold value Ath. Specifically, the bias voltage margin reducing unit 64 sets, as a new bias voltage V, a bias voltage obtained by subtracting a bias voltage margin Vm from the bias voltage V on the space charge limited region side near the boundary position. The bias voltage control unit 74 applies the new bias voltage V to the Wehnelt 224. Then, this state is set as the operating point of the electron emission source 201 at the cathode temperature T that is currently set.

The bias voltage margin Vm may be set appropriately according to the adjustment period described later. Since the longer the adjustment period, the more likely drift occurs, the bias voltage margin Vm may be set large. The bias voltage margin Vm may be set to a voltage of, for example, about 5 to 10% of the bias voltage V. For example, it is preferable to set the bias voltage margin Vm in the range of 100 V to 20 V. For example, when the bias voltage V is-700 V, the bias voltage V reduced by 50 V to the negative side is the bias voltage margin Vm. In other words, 50 V is subtracted from the bias voltage V (−50 V is added to the bias voltage V). In this example, the bias voltage V at the operating point is, for example, −750 V.

Then, the process returns to the current density determination step (S102) to repeat the steps from the current density determination step (S102) to the bias voltage margin reduction step (S142) until the uniformity of the measured current density distribution U becomes equal to or greater than the desired uniformity U0 in the current density distribution determination step (S104).

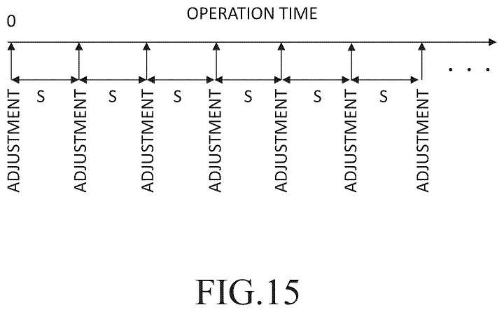

FIG. 15 is a diagram showing an example of an adjustment period in Embodiment 1. In FIG. 15, each of the above-described steps is executed every predetermined period S. In the writing apparatus 100, the current density J and the current density distribution U are measured when the apparatus is started up. In addition, each of the current density J and the current density distribution U is measured every predetermined period S during the operation of the apparatus. For example, the current density J and the current density distribution U are measured once a week or once a month. Then, each time, an electron beam is adjusted, in other words, the operating point for the driving of the electron emission source 201 is adjusted.

Next, a method of writing processing will be described. The writing data processing unit 40 reads out writing data stored in the storage device 140, and generates beam irradiation time data for writing with multiple beams. The writing control unit 42 rearranges the beam irradiation time data in the order of shots according to the writing sequence. Then, the beam irradiation time data is transmitted to the deflection control circuit 130 in the order of shots. The deflection control circuit 130 outputs a blanking control signal to the blanking aperture array mechanism 204 in the shot order, and also outputs a deflection control signal to the DAC amplifier units 132 and 134 in the shot order. The writing mechanism 150 (irradiation mechanism) controlled by the writing control unit 42 irradiates the target object 101 with an electron beam emitted from the electron emission source 201 and subjected to beam adjustment. For example, the writing mechanism 150 herein writes a pattern on the target object 101 using an electron beam emitted from an electron emission source 201 and subjected to beam adjustment.

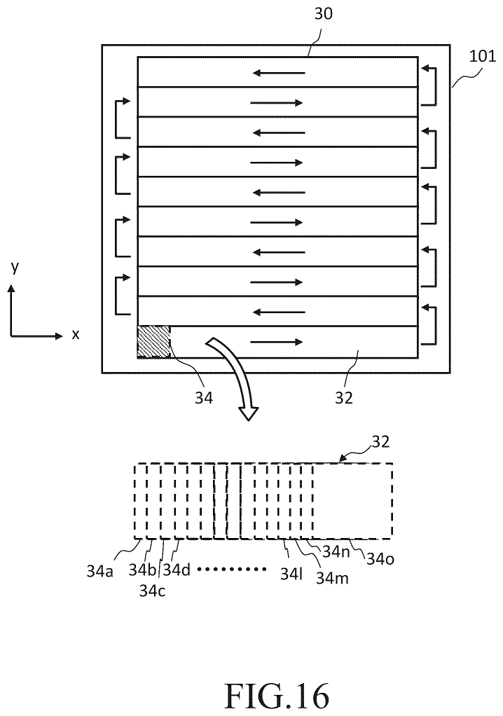

FIG. 16 is a conceptual diagram for explaining an example of the writing operation in Embodiment 1. As shown in FIG. 16, a writing region 30 of the target object 101 is virtually divided into a plurality of rectangular striped regions 32 with a predetermined width in the y direction, for example. First, the XY stage 105 is moved to make an adjustment so that an irradiation region 34 that can be irradiated with one shot of the multiple beams 20 is located at the left end of the first striped region 32 or further to the left, and writing is started. When writing the first striped region 32, the XY stage 105 is moved, for example, in the −x direction, so that the writing proceeds relatively in the x direction. The XY stage 105 is continuously moved, for example, at a constant speed. After the end of the writing in the first striped region 32, the stage position is moved in the −y direction and the irradiation region 34 is adjusted so as to be located relatively in the y direction at the right end of the second striped region 32 or further to the right, and then the XY stage 105 is moved, for example, in the x direction, to perform writing in the same manner in the −x direction. The writing time can be shortened by performing writing while changing the direction alternately, for example, by performing writing in the x direction in the third striped region 32 and performing writing in the −x direction in the fourth striped region 32. However, writing may proceed in the same direction when writing each striped region 32, without being limited to the case of performing writing while changing the direction alternately. In one shot, by multiple beams formed by passing through each hole 22 in the shaping aperture array substrate 203, a plurality of shot patterns, up to the same number as the number of holes 22 formed in the shaping aperture array substrate 203, are formed at a time. In addition, although a case where each striped region 32 is written once at a time is shown in the example of FIG. 12, the invention is not limited thereto. It is also preferable to perform multi-writing, in which the same region is written multiple times. When multi-writing is performed, it is preferable to set the striped region 32 for each pass while shifting the position.

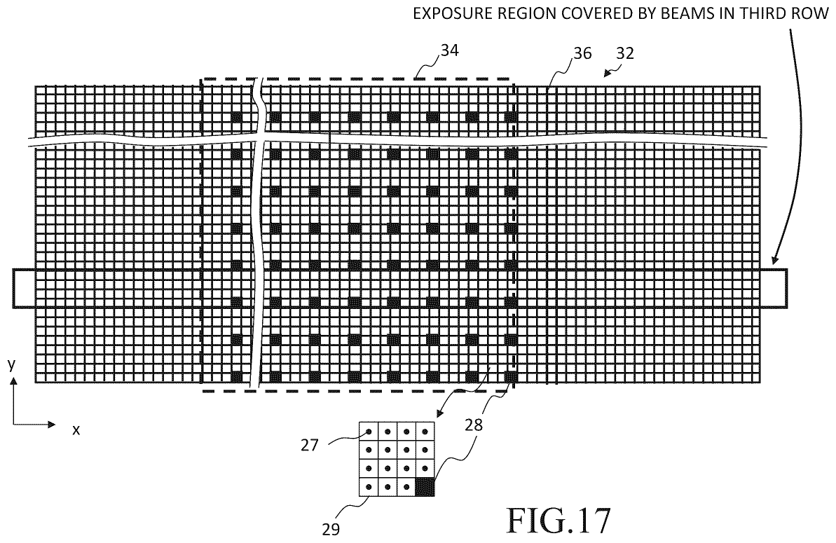

FIG. 17 is a diagram showing an example of a multi-beam irradiation region and a pixel to be written in Embodiment 1. In FIG. 17, for example, a plurality of control grids 27 (design grids), which are arranged in a lattice pattern at the beam size pitch of the multiple beams 20 on the surface of the target object 101, are set in a striped region 32. For example, it is preferable that the arrangement pitch is about 10 nm. The plurality of control grids 27 are designed irradiation positions of the multiple beams 20. The arrangement pitch of the control grids 27 is not limited to the beam size, and may be any size that can be controlled as the deflection position of the deflector 209 regardless of the beam size. Then, a plurality of pixels 36, which are centered on each control grid 27 and are virtually divided into a mesh shape having the same size as the arrangement pitch of the control grids 27, are set. Each pixel 36 is an irradiation unit region per one beam of multiple beams. In the example of FIG. 16, a case is shown in which the writing region of the target object 101 is divided into a plurality of striped regions 32, for example, in the y direction with substantially the same width as the size of the irradiation region 34 (writing field) that can be irradiated by one-time irradiation using the multiple beams 20. The size of the irradiation region 34 in the x direction can be defined as a value obtained by multiplying the inter-beam pitch of the multiple beams 20 in the x direction by the number of beams in the x direction. The size of the irradiation region 34 in the y direction can be defined as a value obtained by multiplying the inter-beam pitch of the multiple beams 20 in the y direction by the number of beams in the y direction. In addition, the width of the striped region 32 is not limited to this. It is preferable that the width of the striped region 32 is n times (n is an integer of 1 or more) the size of the irradiation region 34. In the example of FIG. 17, for example, a 512×512 array of multiple beams is abbreviated to an 8×8 array of multiple beams. Then, in the irradiation region 34, a plurality of pixels 28 (beam writing positions) that can be irradiated with one shot of the multiple beams 20 are shown. In other words, the pitch between adjacent pixels 28 is a designed pitch between the multiple beams. In the example of FIG. 17, one sub-irradiation region 29 is formed by a region surrounded by the inter-beam pitch. In the example of FIG. 17, a case is shown in which each sub-irradiation region 29 is formed by 4×4 pixels.

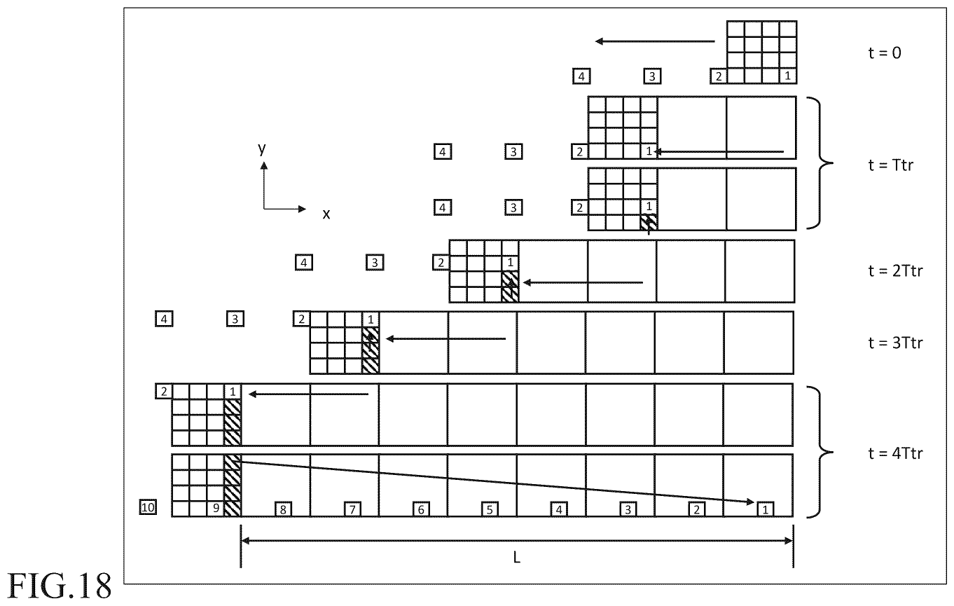

FIG. 18 is a diagram for explaining an example of a writing method using multiple beams in Embodiment 1. FIG. 18 shows a part of the sub-irradiation region 29 to be written by beams at coordinates (1, 3), (2, 3), (3, 3), . . . , (512, 3) in the third row in the y direction, among multiple beams for writing the striped region 32 shown in FIG. 16. In the example of FIG. 18, for example, a case is shown in which four pixels are written (exposed) while the XY stage 105 moves by the distance of eight beam pitches. The irradiation region 34 is caused to follow the movement of the XY stage 105 by collectively deflecting all of the multiple beams 20 with the deflector 208, so that the relative position of the irradiation region 34 with respect to the target object 101 does not shift due to the movement of the XY stage 105, while writing (exposing) the four pixels 36. In other words, tracking control is performed. In the example of FIG. 18, a case is shown in which one tracking cycle is performed by writing (exposing) four pixels while shifting the pixel 36 to be irradiated with the beam in the y direction for each shot during movement by the distance of eight beam pitches.

Specifically, the writing mechanism 150 irradiates each control grid 27 with a corresponding ON beam of the multiple beams 20 for a writing time (irradiation time or exposure time) corresponding to each control grid 27 within the maximum irradiation time Ttr among the irradiation times of each beam of the multiple beams in the shot. The maximum irradiation time Ttr is set in advance. In practice, a time obtained by adding the settling time of beam deflection to the maximum irradiation time Ttr is the shot cycle, but the settling time of beam deflection is omitted and the maximum irradiation time Ttr is shown as the shot cycle herein. Then, when one tracking cycle ends, the tracking control is reset to return the tracking position to the starting position of the next tracking cycle.

In addition, since the writing of the first pixel column from the right of each sub-irradiation region 29 has been completed, in the next tracking cycle after tracking reset, the deflector 209 first deflects the beam so as to align (shift) the writing position of the beam corresponding to the control grid 27 in the first row from the bottom and the second pixel from the right of each sub-irradiation region 29.

As described above, during the same tracking cycle, each shot is performed while shifting the position by one control grid 27 (pixel 36) at a time by the deflector 209 in a state in which the relative position of the irradiation region 34 with respect to the target object 101 is controlled to be the same by the deflector 208. Then, after the end of one tracking cycle, the tracking position of the irradiation region 34 is returned, and then, as shown in the lower part of FIG. 18, the first shot position is aligned to a position shifted by, for example, one control grid (one pixel), and each shot is performed while shifting the position by one control grid (one pixel) by the deflector 209 while performing the next tracking control. By repeating this operation while writing the striped region 32, the position of the irradiation region 34 moves sequentially to the irradiation regions 34a to 340 as shown in the lower diagram of FIG. 16, and accordingly, the striped region is written.

Then, which control grid 27 (pixel 36) on the target object 101 is to be irradiated with which of the multiple beams is determined by the writing sequence. Assuming that the sub-irradiation region 29 is a region of n×n pixels, n control grids (n pixels) are written in one tracking operation. In the next tracking operation, n pixels are similarly written by a beam different from the beam described above. Thus, since n pixels are written at a time using different beams in n tracking operations, all pixels within one region of n×n pixels are written. A similar operation is performed at the same time for other sub-irradiation regions 29 of n×n pixels within the multi-beam irradiation region, so that writing is performed in the same manner.

The above-described beam adjustment is performed when the target object 101 is not being written. For example, the beam adjustment is performed before writing on the next target object is started after the end of writing on one target object. Alternatively, the beam adjustment is performed before the end of writing on the target object after the start of writing on the target object. For example, the beam adjustment is performed before the writing of the next striped region 32 is started after the end of writing of the striped region 32.

As described above, according to Embodiment 1, it is possible to search for the operating point of the electron emission source 201 (thermal electron source) in a path where an electron beam emitted from the electron emission source 201 does not go deep into the temperature limited region.

The embodiments have been described above with reference to specific examples. However, the invention is not limited to these specific examples.

In addition, the functions of the processes described in Embodiment 1 may be executed by a computer. Then, a program for causing a computer to execute such functions of the processes may be stored, for example, in a non-transitory, tangible, and computer-readable storage medium, such as a magnetic disk drive.

In addition, the description of parts that are not directly required for the description of the invention, such as the apparatus configuration or the control method, is omitted. However, the required apparatus configuration, control method, and the like can be appropriately selected and used. For example, although the description of the control unit configuration for controlling the writing apparatus 100 is omitted, it is needless to say that the required control unit configuration can be appropriately selected and used.

In addition, all electron beam adjustment methods, electron beam writing apparatuses, and programs (or non-transitory computer-readable storage media storing a program) that include the elements of the invention and that can be appropriately modified by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam adjustment method, comprising:
setting, to a predetermined value, a temperature of a cathode in a thermal electron source configured to have the cathode, an anode electrode controlled to have a positive potential with respect to the cathode, and a Wehnelt electrode arranged between the cathode and the anode electrode and controlled to have a negative potential with respect to the cathode, and emit an electron beam from the cathode to the anode electrode;
changing a bias voltage applied to the Wehnelt electrode while maintaining the temperature of the cathode at the predetermined value;
measuring an emission current in a case that the bias voltage is changed while maintaining the temperature of the cathode at the predetermined value; and
calculating a determination parameter based on an amount of change in the emission current in a case that the bias voltage is changed,
wherein each of the changing of the bias voltage, the measuring of the emission current, and the calculating of the determination parameter is repeated within a range where the determination parameter does not exceed a threshold value while maintaining the temperature of the cathode at the predetermined value.

2. The method according to claim 1,
wherein the determination parameter is calculated by dividing a rate of change in the emission current in a case that the bias voltage is changed by an amount of change in the bias voltage.

3. The method according to claim 1, further comprising:
comparing the determination parameter with the threshold value; and
reducing the bias voltage to a negative side by a width set in advance in a case that that the determination parameter reaches the threshold value.

4. The method according to claim 1,
wherein each of the changing of the bias voltage, the measuring of the emission current, and the calculating of the determination parameter is repeated to make the determination parameter approach the threshold value from a state where the determination parameter is greater than the threshold value.

5. The method according to claim 1,
wherein each of the setting, the changing, the measuring, and the calculating is performed every predetermined period.

6. The method according to claim 1, further comprising:
determining whether or not a current density of the electron beam is greater than a desired current density.

7. The method according to claim 6, further comprising:
reducing a current bias voltage applied to the Wehnelt electrode in a case that the current density of the electron beam is equal to or greater than the desired current density as a result of the determination; and
lowering a set temperature of the cathode after the bias voltage is reduced.

8. The method according to claim 7,
wherein, after lowering the temperature of the cathode, each of the changing of the bias voltage, the measuring of the emission current, and the calculating of the determination parameter is repeated until the determination parameter reaches a threshold value while maintaining the temperature of the cathode at a lowered temperature.

9. The method according to claim 6, further comprising:
increasing a set temperature of the cathode in a case that the current density of the electron beam is smaller than the desired current density as a result of the determination.

10. The method according to claim 9,
wherein, after increasing the temperature of the cathode, each of the changing of the bias voltage, the measuring of the emission current, and the calculating of the determination parameter is repeated until the determination parameter reaches a threshold value while maintaining the temperature of the cathode at an increased temperature.

11. An electron beam apparatus, comprising:
a thermal electron source configured to have a cathode, an anode electrode controlled to have a positive potential with respect to the cathode, and a Wehnelt electrode arranged between the cathode and the anode electrode and controlled to have a negative potential with respect to the cathode, and emit an electron beam from the cathode to the anode electrode;
a temperature setting circuit configured to set a temperature of the cathode to a predetermined value;
a bias voltage control circuit configured to change a bias voltage applied to the Wehnelt electrode while maintaining the temperature of the cathode at the predetermined value;
an emission current measurement circuit configured to measure an emission current in a case that the bias voltage is changed while maintaining the temperature of the cathode at the predetermined value;
a parameter calculation circuit configured to calculate a determination parameter based on an amount of change in the emission current in a case that the bias voltage is changed; and
an irradiation mechanism configured to irradiate a target object with the electron beam emitted from the thermal electron source,
wherein each of an operation of changing the bias voltage, an operation of measuring the emission current, and an operation of calculating the determination parameter is repeated within a range where the determination parameter does not exceed a threshold value while maintaining the temperature of the cathode at the predetermined value.

12. The apparatus according to claim 11,
wherein the determination parameter is calculated by dividing a rate of change in the emission current in a case that the bias voltage is changed by an amount of change in the bias voltage.

13. A non-transitory computer-readable storage medium storing a program for causing a computer to execute processing comprising:
setting, to a predetermined value, a temperature of a cathode in a thermal electron source having the cathode, an anode electrode controlled to have a positive potential with respect to the cathode, and a Wehnelt electrode arranged between the cathode and the anode electrode and controlled to have a negative potential with respect to the cathode, and emit an electron beam from the cathode to the anode electrode;
changing a bias voltage applied to the Wehnelt electrode while maintaining the temperature of the cathode at the predetermined value;
measuring an emission current in a case that the bias voltage is changed while maintaining the temperature of the cathode at the predetermined value;
storing a measured emission current in a storage device;
reading the emission current from the storage device and calculating a determination parameter based on an amount of change in the emission current in a case that the bias voltage is changed; and
repeating each of the changing of the bias voltage, the measuring of the emission current, and the calculating of the determination parameter within a range where the determination parameter does not exceed a threshold value while maintaining the temperature of the cathode at the predetermined value.

14. The storage medium according to claim 13,
wherein the determination parameter is calculated by dividing a rate of change in the emission current in a case that the bias voltage is changed by an amount of change in the bias voltage.
